(19) United States
(12) Patent Application Publication
(10) Pub. No.: US 2026/0341626 A1
(43) Pub. Date: Oct. 29, 2026

(54) CATHODE CLAMP AND ION SOURCE

(71) Applicant: NISSIN ION EQUIPMENT CO., LTD., Koka-city (JP)

(72) Inventor: George SACCO, Groveland, MA (US)

(73) Assignee: NISSIN ION EQUIPMENT CO., LTD., Koka-city (JP)

(21) Appl. No.: 19/191,311

(22) Filed: Apr. 28, 2025

(51) Int. Cl. H01J 37/08; H01J 37/317

(52) U.S. Cl. CPC H01J 37/08; H01J 37/3171; H01J 2237/032; H01J 2237/061

(57) ABSTRACT

A cathode clamp includes a first elongated member, a second elongated member spaced apart from the first elongated member in a first direction, and a connecting portion connected to a proximal end of each of the first elongated member and the second elongated member. Distal ends of the first elongated member and the second elongated member clamp lateral sides of a cathode to support the cathode in an orthogonal direction that is orthogonal to the first direction.

### BACKGROUND

### 1. Field

The present disclosure relates to a cathode clamp to clamp a cathode and an ion source that uses the cathode clamp.

### 2. Description of Related Art

In an ion implanter, an indirectly heated cathode ion source is used as a long-life ion source. In the indirectly heated cathode ion source, a cathode is heated by thermal electrons emitted from a filament. However, in some cases, components used to hold the cathode may be deformed rendering the operation of the indirectly heated cathode ion source inoperable.

### SUMMARY

According to an aspect of one or more embodiments, there is provided a cathode clamp to clamp a cathode, the cathode clamp comprising a first elongated member; and a second elongated member which is paired with the first elongated member. The first elongated member and the second elongated member have a connecting portion that connects the first elongated member and the second elongated member to each other and a separating portion at which the first elongated member and the second elongated member are separated from each other, and the cathode is clamped by elastic deformation of the first elongated member and the second elongated member in the separating portion.

According to another aspect of one or more embodiments, there is provided a cathode clamp used in an indirectly heated cathode ion source, the cathode clamp comprising a first elongated member; a second elongated member spaced apart from the first elongated member in a first direction; and a connecting portion connected to a proximal end of each of the first elongated member and the second elongated member. Distal ends of the first elongated member and the second elongated member are configured to clamp lateral sides of a cathode to support the cathode in an orthogonal direction that is orthogonal to the first direction.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of an ion source, according to some embodiments;

FIG. 2 illustrates an example of a perspective view of a cathode clamp, according to some embodiments;

FIG. 3 illustrates an example of a plan view of a cathode clamp, according to some embodiments;

FIG. 4 illustrates an example of a plan view of a cathode clamp, according to some embodiments;

FIG. 5 illustrates an example of an ion source, according to some embodiments;

FIG. 6 illustrates an example of a plan view of a cathode clamp, according to some embodiments;

FIG. 7 illustrates an example of a plan view of a cathode clamp, according to some embodiments;

FIG. 8 illustrates an example of an ion source, according to some embodiments;

FIG. 9 illustrates an example of a plan view of a cathode clamp, according to some embodiments; and

FIG. 10 illustrates an example of an ion source, according to some embodiments.

### DETAILED DESCRIPTION

As described above, in an ion implanter, an indirectly heated cathode ion source is used as a long-life ion source and the indirectly heated ion source is an ion source that heats a cathode with thermal electrons emitted from a filament and the heated cathode emits ionizing electrons from the cathode into a plasma chamber.

The cathode and the filament may be clamped by separate clamping members at a predetermined distance apart each other. The clamping member, e.g., a cathode clamp, for clamping the cathode is composed of two members. The cathode is clamped by the two members using a bolt and nut.

During operation of the ion source, a temperature of the clamping member rises due to effects of energization of the cathode and generation of plasma in the plasma chamber.

When the temperature of the clamp member rises, the bolt and nut undergo thermal deformation, decreasing the fastening force of the bolt and nut.

The decrease in the fastening force makes it impossible to clamp the cathode and causes a contact between the cathode and the filament. As the result, an electrical short circuit occurs between the cathode and the filament, and operation of the ion source becomes impossible.

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

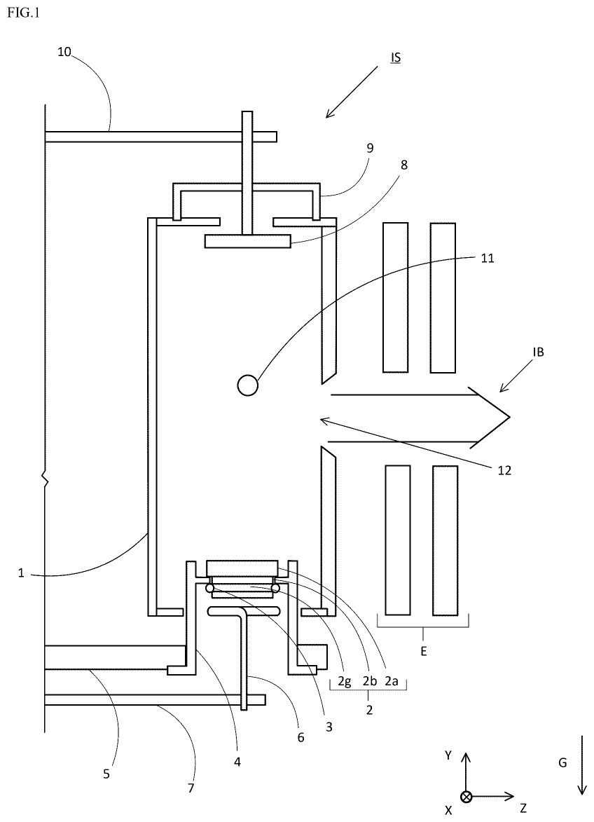

FIG. 1 illustrates an example of an ion source, according to some embodiments. FIG. 1 shows an example of a configuration of an ion source IS. A Z-axis direction shown in FIG. 1 indicates an extraction direction of an ion beam IB described later. A X-axis direction and a Y-axis direction are directions orthogonal to the Z-axis direction. An arrow G indicates a direction of gravity.

In an embodiment, the ion source IS includes a plasma chamber 1, a cathode 2 disposed inside the plasma chamber 1, a cathode holder 4, a cathode clamp 5, a filament 6, a filament clamp 7, a repeller electrode 8 disposed at a position facing the cathode 2, an insulating cup 9, a repeller clamp 10, an extraction opening 12 in a wall of the plasma chamber 1, and an extraction electrode E. The plasma chamber 1 has a gas inlet 11 into which a gas such as BF3, PH3, AsH3, or N2, which is a base of a plasma generated inside the plasma chamber 1, is introduced. Electrons emitted from the cathode 2 ionize the gas introduced from the gas inlet 11 to generate plasma in the plasma chamber 1.

The extraction electrode E is disposed on the downstream of an extraction opening 12 of the plasma chamber 1. The extraction electrode E may include, for example, two electrodes as shown in FIG. 1. Each electrode has an aperture through which the ion beam IB passes. The extraction electrode E extracts the ion beam IB from the plasma generated in the plasma chamber 1 by a potential difference with respect to the plasma chamber 1.

The cathode 2 has, for example, a large diameter portion 2a, a small diameter portion 2b, and a groove 2g. The large diameter portion 2a and the small diameter portion 2b are cylinders having different diameters. The small diameter portion 2b has the groove 2g dug one step from the surface of the small diameter portion 2b in a circumferential direction of the small diameter portion 2b. A wire 3 is attached to the groove 2g. As shown in FIG. 1, a part of the wire 3 protrudes outside the groove 2g. The large diameter portion 2a of the cathode 2 and the wire 3 fix the cathode 2 to the cathode holder 4. For example, a portion of the cathode holder 4 may be sandwiched between the large diameter portion 2a of the cathode 2 and the wire 3 such that the cathode 2 is fixed in position in the direction of gravity by the cathode holder 4. However, a method of fixing or holding the cathode 2 by the cathode holder 4 is not particularly limited as long as the cathode 2 is supported in fixed position by the cathode holder 4.

The cathode clamp 5 clamps the cathode holder 4. The cathode holder 4 supports the cathode 2 and is disposed at a position in the plasma chamber 1. The position may be predetermined. On the back side of the cathode 2 in the −Y axis direction, the filament clamp 7 clamps the filament 6.

When the ion source IS is operated, thermionic electrons emitted from the filament 6 heat the cathode 2 by the energization of the filament 6. The cathode 2 heated by thermionic electrons from the filament 6 emits thermal electrons into the plasma chamber 1. Such an ion source IS is called an indirectly heated cathode ion source.

An electromagnet (not shown) is disposed outside the plasma chamber 1. The electromagnet generates a magnetic field along the Y-axis direction in the plasma chamber 1. Electrons emitted from the cathode 2 are captured by the magnetic field and move to the repeller electrode 8 side. A negative voltage is applied to the repeller electrode 8 through the repeller clamp 10 clamping the repeller electrode 8, and electrons that have moved to the repeller electrode 8 are driven back to the cathode 2.

The outside of the plasma chamber 1 on the side of the repeller electrode 8 is covered with the insulating cup 9. The arrangement of the insulating cup 9 prevents the gas from flowing out from between the plasma chamber 1 and the repeller electrode 8.

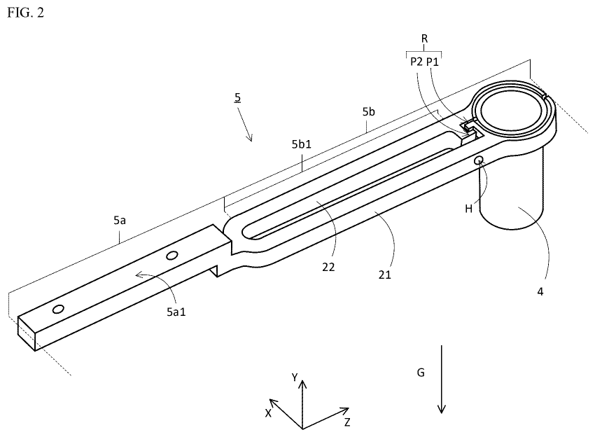

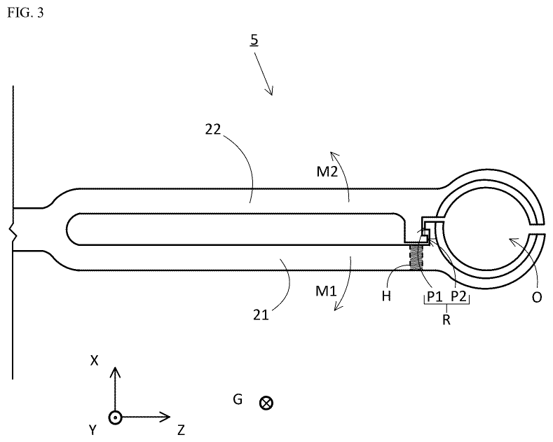

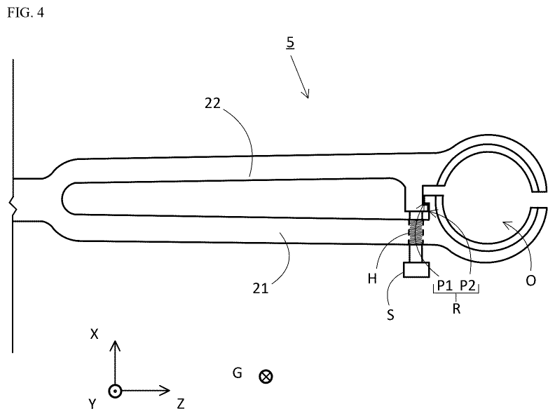

FIG. 2 illustrates an example of a perspective view of a cathode clamp, according to some embodiments, FIG. 3 illustrates an example of a plan view of a cathode clamp, according to some embodiments, and FIG. 4 illustrates an example of a plan view of a cathode clamp, according to some embodiments. FIG. 2 is a perspective view of the cathode clamp 5 clamping the cathode holder 4. FIG. 3 is a ZX plan view of the cathode clamp 5.

The cathode clamp 5 has a first elongated member 21 and a second elongated member 22. The first elongated member 21 and the second elongated member 22 are, for example, members forming a pair as shown in FIG. 2. In the Z axis direction, the first elongated member 21 and the second elongated member 22 are provided with a connecting portion 5a that connects the first and second elongated members 21 and 22 to each other and a separating portion 5b in which the first and second elongated members 21 and 22 are separated from each other. In other words, the first and second elongated members 21 and 22 may be connected to each of other at proximal ends thereof and separated from each other at distal ends thereof.

The connecting portion 5a has a coupling surface 5a1 positioned in the Y axis direction. The coupling surface 5a1 is fixed to an insulating member (not shown) by bolts. The insulating member is fixed to an ion source flange (not shown) on the −Z axis side of the plasma chamber 1.

In the separating portion 5b, the first elongated member 21 and the second elongated member 22 are physically separated from each other and have a parallel portion 5b1 parallel to each other.

The first elongated member 21 and the second elongated member 22 sandwich the cathode holder 4 at the distal end of the separating portion 5b on the opposite side to the connecting portion 5a. By moving the first elongated member 21 and the second elongated member 22 in the directions of arrows M1 and M2 shown in FIG. 3, the dimensions of the opening O may be enlarged, and the cathode holder 4 may be inserted into the opening O. The directions indicated by the arrows M1 and M2 are directions intersecting the Z-axis direction, which is a direction from the connecting portion 5a toward the separating portion 5b.

If the movement in the direction of the arrows M1 and M2 is excessively performed, a force exceeding a yield stress may be applied to the first elongated member 21 and the second elongated member 22, and it may become difficult for each member to return to the original position thereof.

To preventing excessive force from being applied to the respective members, the first elongated member 21 and the second elongated member 22 have projecting portions P1 and P2 that project in respective directions opposed to each other. In some embodiments, the projecting portions P1 and P2 may form a coupling such that the projecting portions P1 and P2 are interlocked with each other as illustrated in FIG. 3 in order to restrict excessive movement in the direction of arrows M1 and M2. The projecting portions P1 and P2 constitute a restricting portion R for restricting excessive movement of the first elongated member 21 and the second elongated member 22 in the directions of the arrows M1 and M2.

The movement of the first elongated member 21 and the second elongated member 22 in the directions of the arrows M1 and M2 may be performed manually. However, since the operation of inserting the cathode holder 4 into the opening O and holding the cathode holder 4 therebetween becomes complicated, the following structure may be adopted.

In an embodiment, a threaded hole H may be formed in the X axis direction at a position of the first elongated member 21 facing the projecting portion P2 of the second elongated member 22.

For example, the threaded hole H has a threaded part inside thereof. In other words, the threaded hole H may have threads on an inside the threaded hole H. As shown in FIG. 4, a gap between the first elongated member 21 and the second elongated member 22 may be widened by inserting a bolt S into the threaded hole H and rotating the bolt S such that threads of the bolt S engage the threads of the threaded hole H and an end of the bolt S pushes against an end of the projecting portion P2 of the second elongated member 22. The threads may be formed over then entire inside surface of the threaded hole H or may be formed only on a part of the inside surface of the threaded hole H.

In the cathode clamp 5 shown in FIG. 2 to 4, the threaded hole H is formed in the first elongated member 21, but this is only an example, and in some embodiments, the threaded hole H may be formed in the second elongated member 22. When the threaded hole H is formed in the second elongated member 22, the threaded hole H of the second elongated member 22 is positioned at a position facing the projecting portion P1 of the first elongated member 21. In some embodiments, the threaded hole H may be formed in each of the first elongated member 21 and the second elongated member 22.

It is advantageous that the first elongated member 21 and the second elongated member 22 described in FIG. 2-4 are formed of materials having a large yield stress, a strong clamping force, and a property that the heat of the cathode holder 4 is not easily dissipated/transferred to the cathode clamp 5 side.

Specific examples of the material of the first elongated member 21 and the second elongated member 22 include at least one of molybdenum, molybdenum alloy, or titanium-zirconium-molybdenum alloy.

By using the cathode clamp 5, a positional deviation of the cathode 2 during the ion source IS operation can be eliminated. In the ion source IS shown in FIG. 1, the cathode 2 and the filament 6 are arranged in the direction of gravity G. In the ion source IS, when a cathode clamp utilizing a related art fastening by bolts and nuts is used, there is a risk that the fastening force is loosened during operation of the ion source IS, and the cathode 2 and the filament 6 are short-circuited. However, in the cathode clamp 5 described with reference to FIG. 2-4, since the first elongated member 21 and the second elongated member 22 are elastically deformed to sandwich the cathode 2 between the members, the risk of short-circuiting between the cathode 2 and the filament 6 due to loosening of the bolt can be reduced.

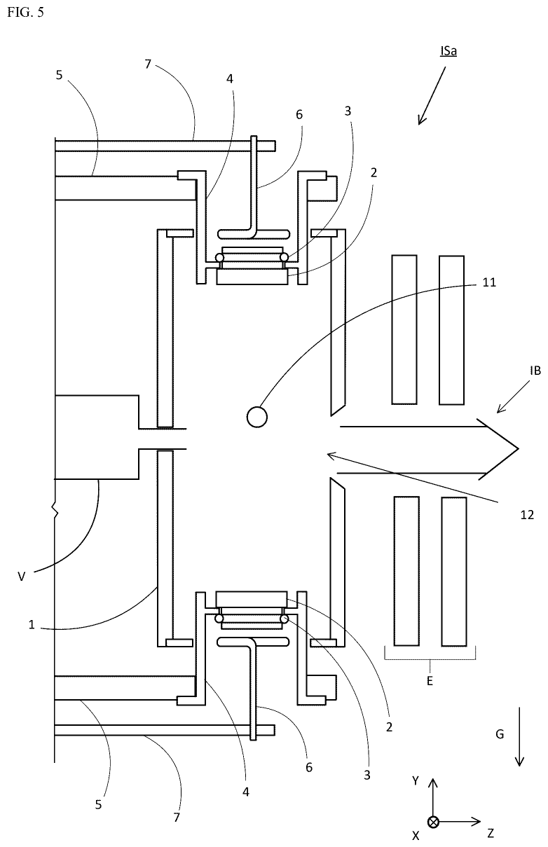

FIG. 5 illustrates an example of an ion source, according to some embodiments.

In an embodiment, an ion source ISa shown in FIG. 5 includes two cathodes 2 opposed to each other in the Y-axis direction. In some embodiments, the plasma chamber 1 may include a vaporizer V for supplying a gas to the plasma chamber 1 in addition to the gas inlet 11.

For example, the vaporizer may generate a gas containing aluminum from an aluminum solid material by using a chloride gas in a vaporizer as described in U.S. patent application Ser. No. 17/714,491, filed Apr. 6, 2022, now U.S. Pat. No. 12,112,915 for “VAPORIZER, ION SOURCE AND METHOD FOR GENERATING ALUMINUM-CONTAINING VAPOR” and/or U.S. patent application Ser. No. 17/945,705, filed Sep. 15, 2022, now U.S. Patent Application Publication No. 2024/098869 for “VAPORIZER, ION SOURCE AND METHOD FOR GENERATING ALUMINUM-CONTAINING VAPOR”, the entire contents of each of which being herein incorporated by reference in their entireties.

For example, the vaporizer may generate a gas from a solid material by using a reactive gas in a vaporizer, and an additional chamber between the vaporizer and the plasma chamber 1 may be placed as described in U.S. patent application Ser. No. 18/621,274, filed Mar. 29, 2024, for “ION SOURCE AND ION IMPLANTER HAVING ION SOURCE”, the entire contents of which being herein incorporated by reference in its entirety.

In some embodiments, the restricting portion R may be omitted from the cathode clamp 5.

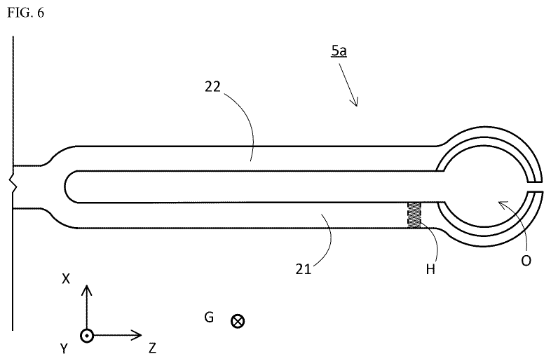

FIG. 6 illustrates an example of a plan view of a cathode clamp, according to some embodiments. For example, a cathode clamp 5a shown in FIG. 6 may omit the restricting portion R. Since there is no restricting portion R, there is a concern that the gap between the first elongated member 21 and the second elongated member 22 may be widened by a force equal to or greater than the yield stress, but by adjusting the length of the bolt S that widens the gap between the two members through the threaded hole H, a force equal to or greater than the yield stress may not be applied to each member.

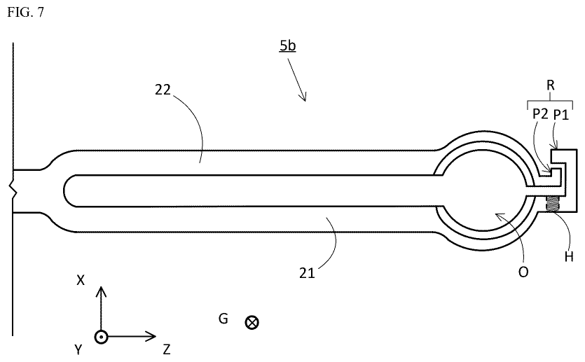

FIG. 7 illustrates an example of a plan view of a cathode clamp, according to some embodiments. In some embodiments, the projecting portions P1 and P2 may not necessarily be provided in the opposing direction of the first elongated member 21 and the second elongated member 22. For example, in a cathode clamp 5b shown in FIG. 7, the projecting portion P1 provided on the first elongated member 21 projects in the X-axis direction, which is the direction facing the second elongated member 22, but the projecting member P2 provided on the second elongated member 22 does not project in the X-axis direction but projects in the Z-axis direction.

Even with the projecting portions P1 and P2 configured as illustrated in FIG. 7, the restricting portion R can be formed to restrict the movement of the first elongated member 21 and the second elongated member 22 in the direction in which the first elongated member 21 and the second elongated member 22 are separated from each other.

That is, it is sufficient that either of the projecting portions P1 and P2 of the first elongated member 21 and the second elongated member 22 projects in the opposing direction of the first elongated member 21 and the second elongated member 22.

However, when the length of the bolt S for widening the first elongated member 21 and the second elongated member 22 is made short, it is advantageous that the projecting portions P1 and P2 provided on the respective members project in the opposing direction of the respective members.

In some embodiments, a configuration may be adopted in which the projecting portions P1 and P2 are provided at the positions shown in FIG. 7, and the threaded hole H is provided at the position shown in FIG. 6.

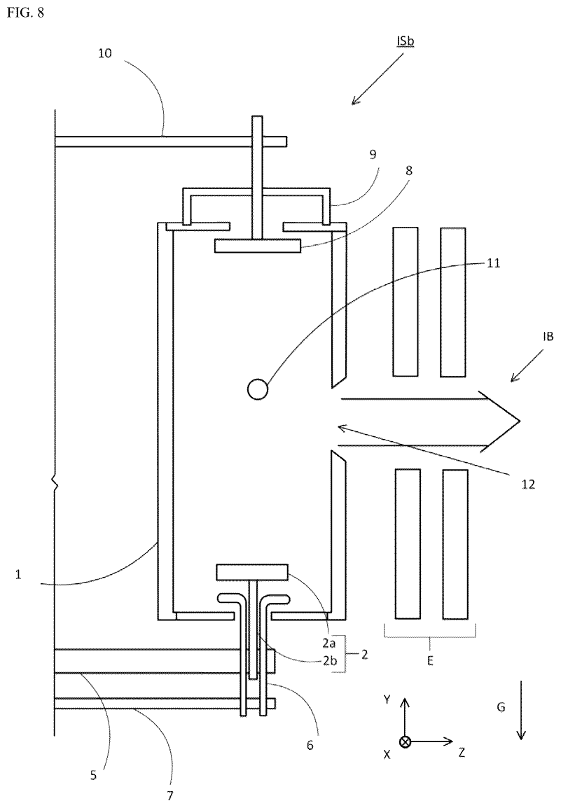

FIG. 8 illustrates an example of an ion source, according to some embodiments. In some embodiments, the cathode 2 may not necessarily be supported by the cathode holder 4. For example, as in an ion source ISb shown in FIG. 8, a structure may be adopted in which the large diameter portion 2a comprising a thermionic emission portion having a thickness in the Y-axis direction constituting the cathode 2 is supported by the small diameter portion 2b in which the small diameter portion 2b is rod-shaped as illustrated in FIG. 8, and the small-diameter portion 2b is fixed by the cathode clamp 5.

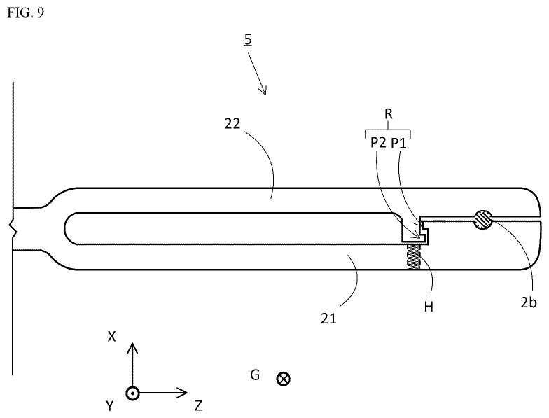

FIG. 9 illustrates an example of a plan view of a cathode clamp, according to some embodiments. FIG. 9 shows a clamping state of the cathode 2 shown in FIG. 8. Even the cathode 2 having such a shape can be held by the cathode clamp 5 described above with respect to FIGS. 1-7.

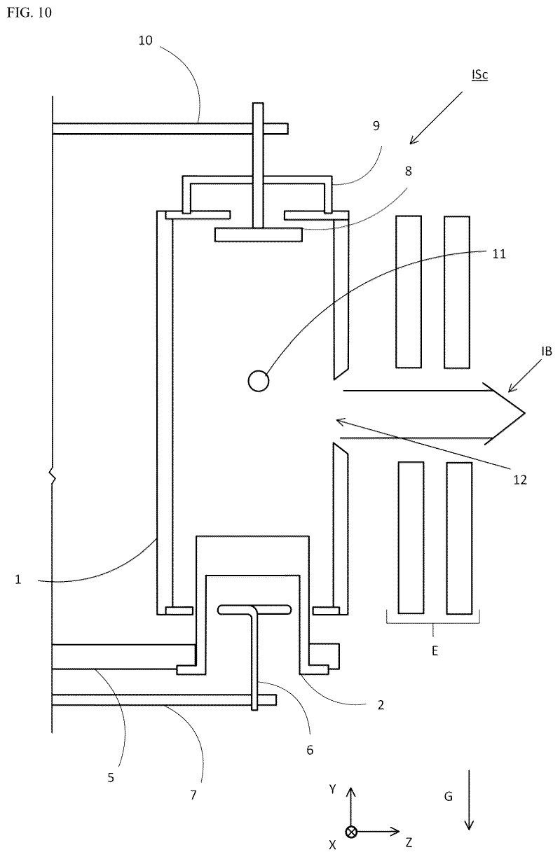

FIG. 10 illustrates an example of an ion source, according to some embodiments. In some embodiments, the cathode 2 used in an ion source ISc shown in FIG. 10 may be clamped by using the cathode clamp 5. The cathode 2 shown in FIG. 10 has a thermionic emission portion that has a thickness in the Y-axis direction at an end portion inside the plasma chamber 1 for emitting the thermal electrons and has a shape having a cylindrical portion below the end portion. The cylindrical portion of the cathode 2 may be clamped by the cathode clamp 5.

The cathode clamp 5 is a clamp for indirectly or directly clamping the cathode 2, and can be used for clamping various kinds of cathodes 2 shown here.

In the ion sources shown in FIGS. 1, 5, 8 and 10, the cathode 2 is disposed inside the plasma chamber 1, but these are only examples and, in some embodiments, the cathode 2 may be disposed outside the plasma chamber 1.

It should be understood that embodiments are not limited to the various embodiments described above, but various other changes and modifications may be made therein without departing from the spirit and scope thereof as set forth in appended claims.

What is claimed is:

1. A cathode clamp to clamp a cathode used in an indirectly heated cathode ion source, the cathode clamp comprising:
a first elongated member; and
a second elongated member which is paired with the first elongated member;
wherein the first elongated member and the second elongated member has a connecting portion that connects the first elongated member and the second elongated member to each other and a separating portion at which the first elongated member and the second elongated member are separated from each other, and
wherein the cathode is clamped by elastic deformation of the first elongated member and the second elongated member in the separating portion.

2. The cathode clamp as recited in claim 1, wherein the first elongated member and the second elongated member independently move in a direction intersecting a direction from the connecting portion toward the separating portion.

3. The cathode clamp as recited in claim 1, further comprising a restricting portion that is configured to restrict movement of the first elongated member and the second elongated member in a separating direction.

4. The cathode clamp as claimed in claim 3, wherein the restricting portion comprises a projecting portion, and
at least one of the first elongated member and the second elongated member includes the projecting portion, and
wherein the projecting portion projects toward the other one of the at least one of the first elongated member and the second elongated member.

5. The cathode clamp as recited in claim 4, wherein both the first elongated member and the second elongated member include the projecting portion.

6. The cathode clamp as recited in claim 1, wherein each of the first elongated member and the second elongated member have a parallel portion and the parallel portions are parallel to each other.

7. The cathode clamp as recited in claim 1, wherein the first elongated member and the second elongated member are made of molybdenum.

8. The cathode clamp as recited in claim 1, wherein the first elongated member and the second elongated member are made of a molybdenum alloy.

9. The cathode clamp as recited in claim 1, wherein the first elongated member and the second elongated member are made of a titanium-zirconium-molybdenum alloy.

10. The cathode clamp as claimed to claim 1, wherein the first elongated member or the second elongated member has a threaded hole formed therein in a direction in which the first elongated member and the second elongated member face each other.

11. The cathode clamp as recited in claim 10, wherein the other one of the first elongated member or the second elongated member includes a projecting portion that projects to face the threaded hole.

12. The cathode clamp as recited in claim 11, wherein the projecting portion facing the threaded hole restricts movement of the first elongated member and the second elongated member away from each other.

13. The cathode clamp as claimed in claim 1, further comprising a cathode holder between the cathode and each of the first elongated member and the second elongated member,
wherein the cathode is supported by the cathode holder being clamped by the first elongated member and the second elongated member.

14. The cathode clamp as recited in claim 1, wherein the cathode includes a thermionic emission portion and a cylindrical portion that supports the thermionic emission portion,
wherein the cylindrical portion is clamped between the first elongated member and the second elongated member by the elastic deformation in the separating portion.

15. The cathode clamp as recited in claim 1, wherein the cathode includes a thermionic emission portion and a rod-shaped support portion that supports the thermionic emission portion,
wherein the rod-shaped support portion is clamped between the first elongated member and the second elongated member by the elastic deformation in the separating portion.

16. An indirectly heated cathode ion source comprising:
the cathode clamp as recited in claim 1;
the cathode that is clamped by the cathode clamp and
a filament disposed below the cathode in a direction of gravity.

17. A cathode clamp used in an indirectly heated cathode ion source, the cathode clamp comprising:
a first elongated member;
a second elongated member spaced apart from the first elongated member in a first direction; and
a connecting portion connected to a proximal end of each of the first elongated member and the second elongated member,
wherein distal ends of the first elongated member and the second elongated member are configured to clamp lateral sides of a cathode to support the cathode in an orthogonal direction that is orthogonal to the first direction.

18. The cathode clamp as recited in claim 17, further comprising a cathode holder between the cathode and each of the first elongated member and the second elongated member.

19. The cathode clamp as recited in claim 17, wherein at least one of the first elongated member or the second elongated member includes a projecting portion, and
wherein the projecting portion projects toward the other one of the at least one of the first elongated member or the second elongated member.

20. The cathode clamp as recited in claim 19, wherein the other one of the at least one of the first elongated member or the second elongated member includes a threaded hole facing the projecting portion.
